(19) United States
(12) Patent Application Publication
(10) Pub. No.: US 2011/0297428 A1
(43) Pub. Date: Dec. 8, 2011

(54) FLEXIBLE FLAT CABLE

(76) Inventor: Shih-Kun YEH, Lu-Chu Hsiang (TW)

(21) Appl. No.: 12/849,333

(22) Filed: Aug. 3, 2010

(30) Foreign Application Priority Data
Jun. 3, 2010 (TW) 099210537

(51) Int. Cl. H05K 1/09; H05K 1/00

(52) U.S. Cl. 174/257; 174/250; 174/258

(57) ABSTRACT

The present invention provides a flexible flat cable which utilizes a first metal plate disposed on the lower surface of at least one end of a first metal shielding layer to achieve the functions of grounding and a reinforcement plate. Besides, since a metal connecting part can be plugged directly into an external socket without additional plastic connector, the manufacturing cost can be reduced.

### BACKGROUND OF THE INVENTION

1. Field of the Invention

The present invention is related to a flexible flat cable, and more particularly to a flexible flat cable with a metal plate which provides grounding and reinforcement functions.

2. Description of the Prior Art

With the rapid advancement of electronic technology, various electronic products have been getting more widely applied in our work and life daily. In different kinds of electronic products, flexible flat cables are used frequently as the means for signal transmission.

In practical applications, a prior art flexible flat cable commonly known arranges a reinforcement plate on one end of the flexible flat cable, and covers the end with a plastic connector. A grounding device is disposed on the plastic connector to electrically connect with the flexible flat cable. Vendors of related industry or research and development (R&D) personnel have been devoted to researching and developing a flexible flat cable achieving the above functions with fewer elements, to lower the manufacturing cost of the product and become more competitive in market.

### SUMMARY OF THE INVENTION

The present invention is directed to providing a flexible flat cable which utilizes a first metal plate disposed on the lower surface of at least one end of a first metal shielding layer to achieve the functions of grounding and a reinforcement plate. Besides, since a metal connecting part of a flexible flat cable can be plugged into an external socket directly without additional plastic connector, the manufacturing cost can be reduced.

The flexible flat cable according to an embodiment includes a first insulating layer, a conductive wire layer, a second insulating layer, a metal shielding layer, at least one first metal plate, and a third insulating layer. The conductive wire layer includes a plurality of metal wires arranged with interspace, and disposed on the first insulating layer. The second insulating layer is disposed on the conductive wire layer and exposes the two ends of the conductive wire layer. The metal shielding layer is disposed on the lower surface of the first insulating layer. The first metal plate is disposed on the lower surface of at least one end of the first metal shielding layer. The third insulating layer covers a portion of the lower surface of the first metal shielding layer.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

FIG. 1 is a schematic diagram of the flexible flat cable according to an embodiment of the present invention;

FIG. 2 is a schematic diagram of the flexible flat cable according to another embodiment of the present invention; and

FIG. 3 is a schematic diagram of the flexible flat cable according to another embodiment of the present invention.

### DESCRIPTION OF THE PREFERRED EMBODIMENT

The detail description of the present invention is provided as follows. The described preferred embodiments are for the purpose of description and illustration, and should not be used to limit the scope of the present invention.

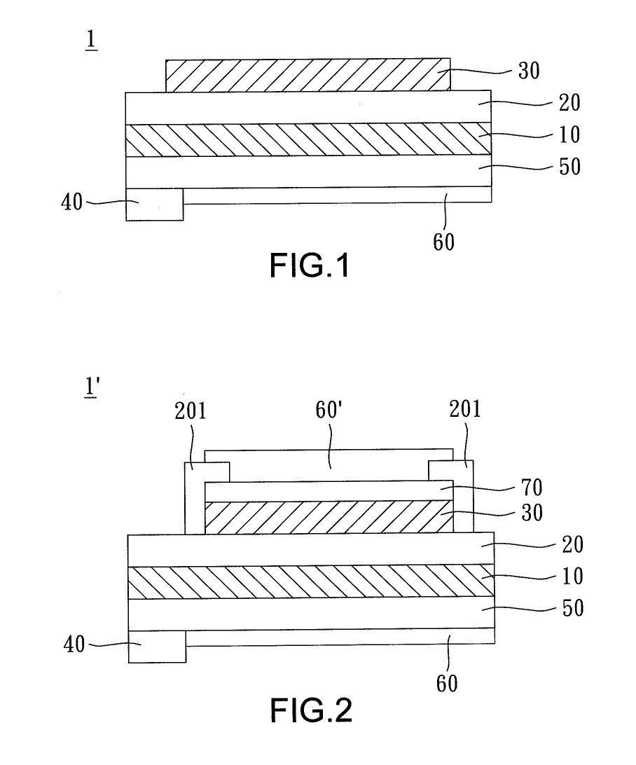

Referring to FIG. 1, FIG. 1 is a schematic diagram of the flexible flat cable 1 according to an embodiment. The flexible flat cable 1 includes a first insulating layer 10, a conductive wire layer 20, a second insulating layer 30, a first metal shielding layer 50, at least one first metal plate 40 and a third insulating layer 60. The conductive wire layer 20 includes a plurality of metal wires arranged with interspace, and disposed on the first insulating layer 10. The second insulating layer 30 is disposed on the conductive wire layer 20 and exposes the two ends of the conductive wire layer 20. The first metal shielding layer 50 is disposed on the lower surface of the first insulating layer 10, for lowering electromagnetic interference and reducing noise interference. The first metal shielding layer 50 can be made by screen printing with conductive carbon paste or silver paste, but it is not limited to be implemented as such. The first metal shielding layer 50 can also be a metal sheet made of a conductive material such as copper or silver, attached with the first insulating layer 10.

Continuing the above description, the first metal plate 40 is disposed on the lower surface of at least one end of the first metal shielding layer 50. The first metal plate 40 is made of a metal material, which can include but not limited to copper or aluminum. The third insulating layer 60 covers part of the lower surface of the first metal shielding layer 50. The first metal plate 40 of the flexible flat cable according to the present embodiment not only can provide the function of grounding by connecting to the external ground element, but also can be a reinforcement plate for cushioning the bumping forces, whereby the probability of the occurrence of rupture is decreased. Besides, the first insulating layer 10, the second insulating layer 30 and the third insulating layer 60 are made of an insulating material which can include but not limited to polyethylene terephthalate (PET). The third insulating layer 60 and the second insulating layer 30 are for blocking the pollution from the external dust and particles, and for preventing scratches or abrasions.

FIG. 2 is a schematic diagram of the flexible flat cable 1′ according to another embodiment. The flexible flat cable 1′ further includes at least a second metal plate 70 disposed on the upper surface of the second insulating layer 30, wherein the plurality of metal wires of the conductive wire layer 20 include at least one ground wire 201. The ground wire is bent and electrically connected with the second metal plate 70 to achieve the effect of grounding. The second metal plate 70 provides the function of reinforcement and rupture prevention. The second metal plate 70 is made of a metal material, which can include but not limited to copper or aluminum. Preferably, another third insulating layer 60′ can be disposed on the second metal plate 70 and covering part of the ground wire 201.

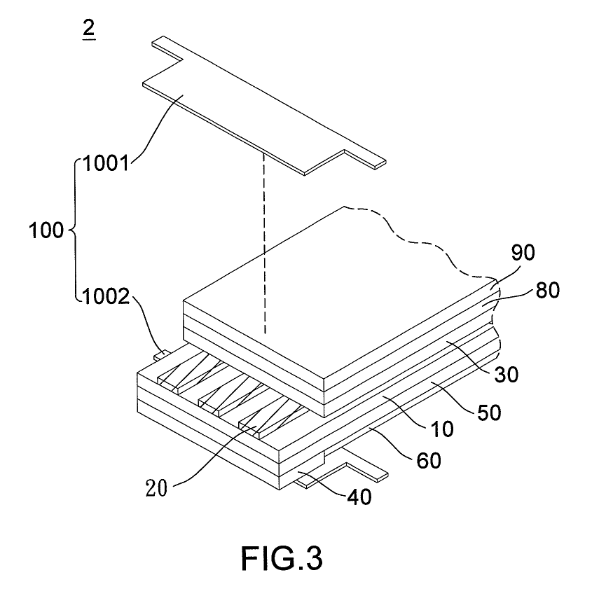

FIG. 3 is a schematic diagram illustrating the flexible flat cable 2 according to another embodiment. The flexible flat cable 2 further includes a second metal shielding layer 80 and a fourth insulating layer 90, wherein the second shielding layer 80 is disposed on the second insulating layer 30, and the fourth insulating layer 90 is disposed on the second metal shielding layer 80. The second metal shielding layer 80 and the first metal shielding layer 50 are both for lowering electromagnetic interference and for reducing noise interference. The second metal shielding layer 80 can be made by screen printing with conductive carbon paste or silver paste, but it is not limited to be implemented as such. The second metal shielding layer 80 can also be a metal sheet made of a conductive material such as copper or silver, attached with the second insulating layer 30. The material of the fourth insulating layer 90 can include but not limited to polyethylene terephthalate (PET). The third insulating layer 60 and the fourth insulating layer 90 are for blocking the pollution from the external dust and particles, and for preventing scratches or abrasions.

Continuing the above description, the flexible flat cable 2 further includes a metal connecting part 100, covering at least one end of the fourth insulating layer 90 and the first metal plate 40, wherein the metal connecting part 100 is electrically insulated from the exposed conductive wire layer 20, and the metal connecting part 100 is electrically connected with the first metal plate 40. It has to be explained that the metal connecting part 100 includes an upper metal cover 1001 and a lower metal cover 1002 working in combination. The lower metal cover 1002 is electrically connected with the first metal plate 40. It is comprehensible that the lower metal cover 1002 of the metal connecting part 100 and the first metal plate 40 can be an element of one piece form, but the present invention is not limited to be implemented as such. The upper metal cover 1001 and the lower metal cover 1002 of the metal connecting part 100 can also be a structure of one piece form. Besides, the structure of the metal connecting part 100 can be plugged directly into a socket (not shown) of another element. By electrically connecting the metal connecting part 100 with a ground element (not shown) of the socket, the first metal plate 40 of the flexible flat cable also achieves the effect of grounding. Therefore, compared with the prior art flexible flat cable, the flexible flat cable 2 of the present embodiment does not need an additional plastic connector, thereby lowering the manufacturing cost. In another embodiment, in order to satisfy the standard of the low voltage differential signal (LVDS) transmission interface to the signal transmission line defined by ANSI/TIA/EIA-644, the characteristic impendence of the flexible flat cable 2 is substantially 100Ω. Moreover, the metal connecting part 100 covering the first metal plate 40 can be a low voltage differential signal connector which can be plugged into a low voltage differential signal socket (not shown) of an electronic device.

In summary, the flexible flat cable of the present invention utilizes the first metal plate disposed on the lower surface of at least one end of the first metal shielding layer to achieve the functions of grounding and a reinforcement plate. Besides, since the metal connecting part can be plugged into the socket directly without any additional plastic connector, the manufacturing cost is reduced.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A flexible flat cable comprising:
a first insulating layer;
a conductive wire layer comprising a plurality of metal wires arranged with interspace, and disposed on the first insulating layer;
a second insulating layer disposed on the conductive wire layer and exposing the two ends of the conductive wire layer;
a metal shielding layer disposed on the lower surface of the first insulating layer;
at least one first metal plate disposed on the lower surface of at least one end of the first metal shielding layer; and
a third insulating layer covering a portion of the lower surface of the first metal shielding layer.

2. The flexible flat cable according to claim 1, further comprising a second metal shielding layer and a fourth insulating layer, wherein the second metal shielding layer is disposed on the second insulating layer, and the fourth insulating layer is disposed on the second metal shielding layer.

3. The flexible flat cable according to claim 2, wherein the material of the second metal shielding layer comprises silver paste or conductive carbon paste.

4. The flexible flat cable according to claim 2, wherein the material of the fourth insulating layer comprises polyethylene terephthalate (PET).

5. The flexible flat cable according to claim 2, further comprising a metal connecting part covering at least one end of the fourth insulation layer and the first metal plate, wherein the metal connecting part is electrically insulated from the exposed conductive wire layer.

6. The flexible flat cable according to claim 5, wherein the metal connecting part comprises an upper metal cover and a lower metal cover working in combination.

7. The flexible flat cable according to claim 6, wherein the lower metal cover of the metal connecting part and the first metal plate can be an element of one piece form.

8. The flexible flat cable according to claim 5, wherein the metal connecting part is of one piece form.

9. The flexible flat cable according to claim 5, wherein the metal connecting part covers the first metal plate is a low voltage differential signal (LVDS) connector.

10. The flexible flat cable according to claim 5, wherein the characteristic impendence of the flexible flat cable is substantially 100Ω.

11. The flexible flat cable according to claim 1, further comprising a second metal plate disposed on the upper surface of the second insulating layer, wherein the metal wires of the conductive wire layer comprise at least one ground wire bent and electrically connected with the second metal plate.

12. The flexible flat cable according to claim 1, wherein material of the first insulating layer, the second insulating layer and the third insulating layer comprise polyethylene terephthalate (PET).
